(19) United States
(12) Patent Application Publication
(10) Pub. No.: US 2008/0054377 A1
(43) Pub. Date: Mar. 6, 2008

(54) Semiconductor Device and Method of Manufacturing the Same

(76) Inventor: JIN HA PARK, Echeon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/849,135

(22) Filed: Aug. 31, 2007

(30) Foreign Application Priority Data
Aug. 31, 2006 (KR) 10-2006-0083333

(51) Int. Cl. H01L 29/78; H01L 21/336

(52) U.S. Cl. 257/408; 438/303; 257/E21.409; 257/E29.266

(57) ABSTRACT

A semiconductor device and a fabricating method thereof are provided. Barrier patterns are formed between a gate and spacers, and between LDD regions and the spacers, thereby inhibiting impurities of the LDD regions from diffusing into the gate.

### CROSS-REFERENCE TO RELATED APPLICATION

The present application claims the benefit under 35 U.S.C. §119 of Korean Patent Application No. 10-2006-0083333, filed Aug. 31, 2006, which is hereby incorporated by reference in its entirety.

### BACKGROUND

Semiconductor devices are widely used as switching devices and memory devices in various fields of the electronics industry. A typical semiconductor device includes at least one transistor of either a bipolar integrated circuit (IC), or a metal oxide semiconductor (MOS) IC.

FIG. 1 is a cross-sectional view of a related art semiconductor device.

Referring to FIG. 1, field layers 2 and 3 are provided in a semiconductor substrate 1, and a gate 4, including a gate oxide layer (not shown) and polysilicon, is provided on the substrate 1 between the field layers 2 and 3.

Lightly-doped drain (LDD) regions 7 and 8 are provided in the substrate 1, near the surface, at both sides of the gate 4. The LDD regions typically include impurities, such as p-type impurities. For example, the LDD regions may include boron (B) ions.

Spacers 5 and 6 are provided on both sides of the gate 4.

Source/drain regions 9 and 10 including boron ions are provided deep in the LDD regions 7 and 8, respectively.

During the manufacturing of a semiconductor device, a thermal treatment is usually performed. The high temperatures often cause diffusion of boron ions from the LDD regions 7 and 8 into the gate 4 through the spacers 5 and 6. The boron ions diffusing into the gate 4 lower the threshold voltage (Vt) of the gate 4. The lowering of the Vt deteriorates electrical characteristics of the semiconductor device and causes abnormal operation.

### BRIEF SUMMARY

Embodiments of the present invention provide a semiconductor device and a fabricating method thereof capable of inhibiting impurities from diffusing into a gate.

In one embodiment, a method of manufacturing a semiconductor device includes: forming a barrier layer on a substrate including a gate and lightly-doped drain (LDD) regions; forming an insulating layer on the barrier layer; patterning the barrier layer and the insulating layer to form a barrier pattern and a spacer on the sides of the gate; and forming source/drain regions on the substrate using the spacers and the gate as a mask.

In another embodiment, a semiconductor device includes: a substrate including a gate and lightly-doped drain (LDD) regions; spacers on the side surfaces of the gate; a barrier pattern between the gate and each spacer and between each LDD region and the spacer on it; and a source/drain region under each LDD region.

According to embodiments, the barrier patterns impede impurity ions of the LDD regions from diffusing into the gate via the spacers, thereby inhibiting a decrease in the threshold voltage (Vt).

The details of one or more embodiments are set forth in the accompanying drawings and the detailed description. Other features will be apparent to those skilled in the art from the description, the drawings, and the appended claims.

### BRIEF DESCRIPTION OF THE DRAWINGS

FIG. 1 is a cross-sectional view of a related art semiconductor device.

FIG. 2 is a cross-sectional view of a semiconductor device according to an embodiment of the present invention.

FIGS. 3A through 3E are cross-sectional views for illustrating a method of manufacturing a semiconductor device according to an embodiment of the present invention.

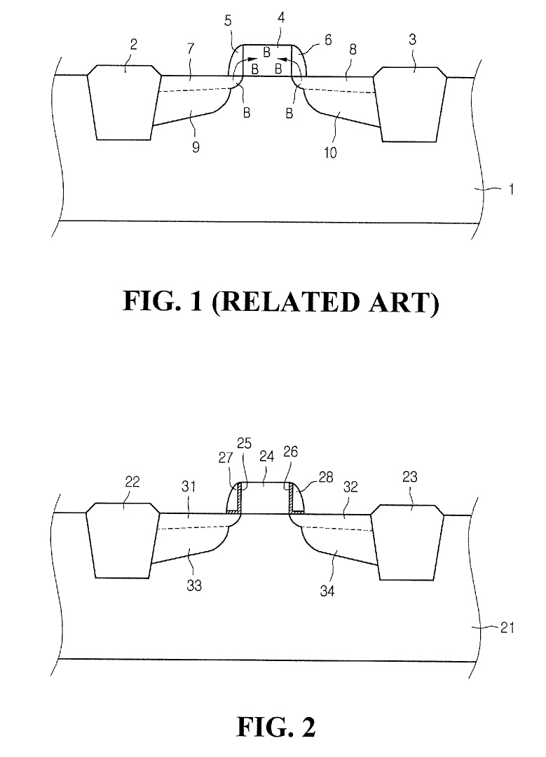

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Referring to FIG. 2, field layers 22 and 23 can be provided in a field region of a substrate 21. An active region can be defined between the field layers 22 and 23, and a unit transistor can be provided in the active region. The field layers 22 and 23 can be formed by, for example, thermal oxidation.

A gate oxide layer (not shown) can be formed on the substrate 21 including the field layers 22 and 23, and polysilicon (not shown) can be deposited on the gate oxide layer. The polysilicon can be deposited by, for example, a chemical vapor deposition (CVD) process. Then, the polysilicon and the gate oxide layer can be patterned by a photolithography process to form a gate 24.

Impurities can be implanted at a low concentration near a surface of the substrate 21 by using the gate 24 as a mask, thereby forming lightly-doped drain (LDD) regions 31 and 32. In an embodiment, the impurities are n-type impurities. In an alternative embodiment, the impurities are p-type impurities. For example, the impurities can be boron (B) ions.

Spacers 27 and 28 can be provided on both side surfaces of the gate 24 on the substrate 21 including the LDD regions 31 and 32.

A barrier pattern 25 can be formed on the side surface and the bottom surface of the spacer 27, such that it is between the gate 24 and the spacer 27. Another barrier pattern 26 can also be formed on the side surface and the bottom surface of the spacer 28, such that it is between the gate 24 and the spacer 28 at the other side of the gate 24. Thus, the height of each of the barrier patterns 25 and 26 is approximately the same as the height of the gate 24. The length extending from the gate along a top surface of an LDD region of each of the barrier patterns 25 and 26 is approximately the same as that of each of the spacers 27 and 28. The barrier patterns 25 and 26 inhibit impurities in the LDD regions 31 and 32 from diffusing into the gate 24.

As illustrated in FIG. 2, the spacers 27 and 28 have side surfaces along the sidewalls of the gate 24 and bottom surfaces along a portion of the LDD regions 31 and 32, respectively. Accordingly, since the barrier patterns 25 and 26 are formed at portions where the spacers 27 and 28 contact the gate 24 and the LDD regions 31 and 32, impurities of the LDD regions 31 and 32 are impeded by the barrier patterns 25 and 26 from diffusing into the gate 24. An undesired decrease in threshold voltage (Vt) can be inhibited, thereby improving the electrical characteristics of the device.

Impurities can be implanted at a high concentration into the substrate 21 deeper than the LDD regions 31 and 32, by using the gate 24 and the spacers 27 and 28 as a mask, thereby forming source/drain regions 33 and 34. In many embodiments, the impurities implanted at a high concentration are the same types of impurities that were implanted at a low concentration into the LDD regions. Thus, in an embodiment, the impurities implanted at a high concentration can be n-type impurities. In an alternative embodiment, the impurities implanted at a high concentration can be p-type impurities. For example, the impurities implanted at a high concentration can be boron (B) ions.

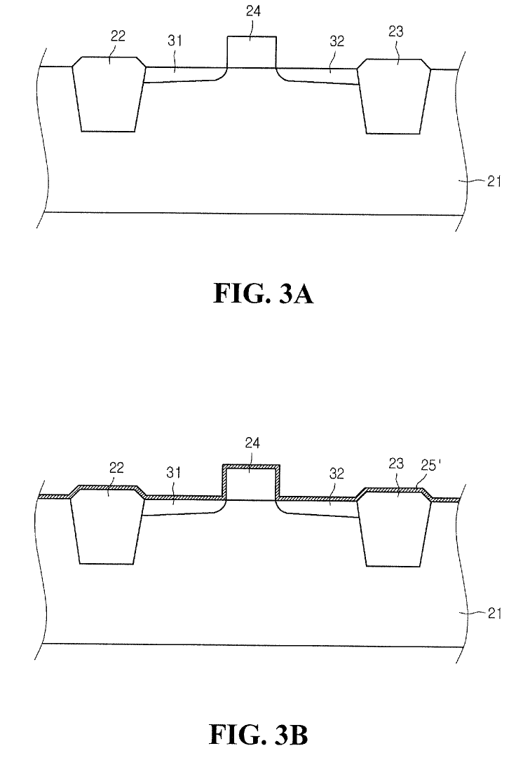

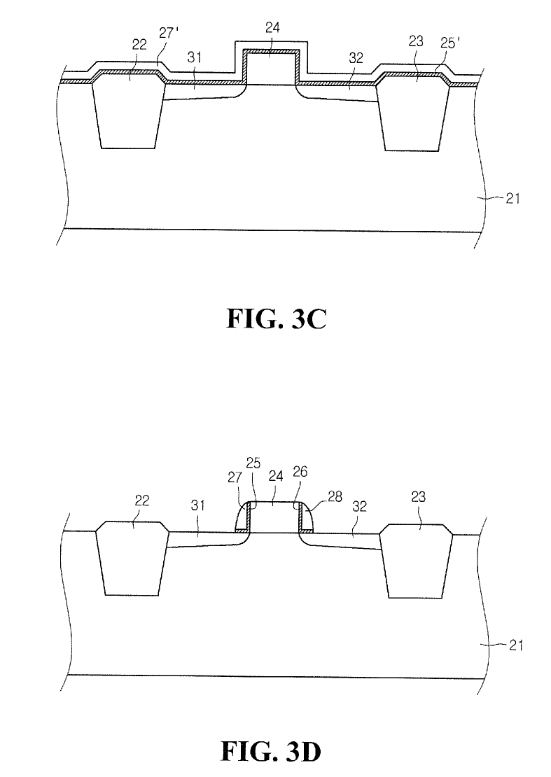

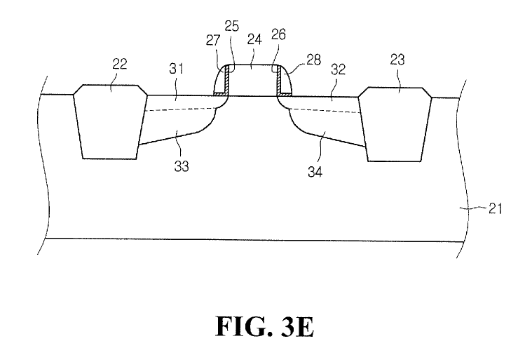

FIGS. 3A through 3E are cross-sectional views for describing a process of manufacturing a semiconductor device according to an embodiment.

Referring to FIG. 3A, field layers 22 and 23 can be formed in a substrate 21 by thermal oxidation. The field layers 22 and 23 can define an active region in which a unit transistor may be formed.

An ion implantation process (not shown) can be performed in order to determine a threshold voltage (Vt) on the substrate 21. A gate oxide layer and polysilicon can be sequentially formed and patterned to form a gate 24 on the substrate 21 between the field layers 22 and 23.

Impurities can be implanted at a low concentration through an ion implantation process by using the gate 24 as a mask, thereby forming lightly-doped drain (LDD) regions 31 and 32. The LDD regions 31 and 32 can be formed near the surface of the substrate 21 on both sides of the gate 24 within the active region between the field layers 22 and 23. In an embodiment, the impurities implanted at a low concentration can be n-type impurities. In an alternative embodiment, the impurities can be p-type impurities. For example, the impurities can be boron (B) ions.

Referring to FIG. 3B, a barrier layer 25′ can be formed on the substrate 21 including the LDD regions 31 and 32.

In one embodiment, the barrier layer 25′ can be formed by a plasma process using nitride. The process conditions of the plasma process can include a pressure of from about 5 mTorr to about 20 mTorr and a flux of from about 100 sccm to about 200 sccm. The plasma process causes nitride ions to penetrate into the surface of the substrate 21, thereby forming the barrier layer 25′ of a nitride on the surface of the substrate 21.

In an alternative embodiment, the barrier layer 25′ can be formed by a chemical vapor deposition (CVD) process using silane (SiH₄) and ammonia (NH₃). The silane and nitride can react with each other during the CVD process, thereby forming the barrier layer 25′ of silicon nitride (SiN).

Referring to FIG. 3C, an insulating layer 27′ can be deposited on the substrate 21 including the barrier layer 25′. In an embodiment, the insulating layer 27′ can be thick compared to the barrier layer 25′.

Referring to FIG. 3D, the barrier layer 25′ and the insulating layer 27′ can be patterned by an etching process to form a spacer 27 and a barrier pattern 25 on one side of the gate 24, and another spacer 28 and another barrier pattern 26 on the other side of the gate 24. The barrier pattern 25 can be formed on the LDD region 31 contacting the bottom surface of the spacer 27, and the barrier pattern 26 can be formed on the LDD region 32 contacting the bottom surface of the spacer 28. The barrier patterns 25 and 26 can also be formed on the side surfaces of the gate 24 to each have the same height as the gate 24.

Thus, the barrier patterns 25 and 26 can insulate the spacers 27 and 28 from the gate 24 and the LDD regions 31 and 32, inhibiting the impurities of the LDD regions 31 and 32 from diffusing into the gate 24. The impurities of the LDD regions 31 and 32 are inhibited from diffusing into the spacers 27 and 28, respectively, by the barrier patterns 25 and 26. If some impurities were to diffuse into the spacers 27 and 28, they are inhibited from diffusing into the gate 24 by the barrier patterns 25 and 26 formed on the side surfaces of the gate 24. Since the impurities of the LDD regions 31 and 32 are inhibited from diffusing into the gate 24, the threshold voltage (Vt) is substantially unchanged, thereby improving the characteristics of a device.

Referring to FIG. 3E, impurities can be implanted at a high concentration into the substrate 21 deeper than the LDD regions 31 and 32 by using the gate 24 and the spacers 27 and 28 as a mask, thereby forming source/drain regions 33 and 34. In many embodiments, the impurities implanted at a high concentration are the same types of impurities that were implanted at a low concentration into the LDD regions. Thus, in an embodiment, the impurities implanted at a high concentration can be n-type impurities. In an alternative embodiment, the impurities implanted at a high concentration can be p-type impurities. For example, the impurities implanted at a high concentration can be boron (B) ions.

Unit transistors can be formed in the active region between the field layers 22 and 23.

Device characteristics can be improved since diffusion of impurities into the gate is inhibited.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming a barrier layer on a substrate including a gate and lightly-doped drain regions;
forming an insulating layer on the barrier layer;
patterning the barrier layer and the insulating layer to form a first barrier pattern, a first spacer, a second barrier pattern, and a second spacer; and
forming source/drain regions in the substrate using the first spacer, the second spacer, and the gate as a mask, wherein the first spacer is formed adjacent to a first side surface of the gate, and wherein the second spacer is formed adjacent to a second side surface of the gate.

2. The method according to claim 1, wherein the first and second barrier patterns are formed between the gate and the first and second spacers.

3. The method according to claim 1, wherein the first and second barrier patterns are formed between the first and second spacers and a portion of the lightly-doped drain regions.

4. The method according to claim 1, wherein forming the barrier layer comprises performing a plasma process using nitride.

5. The method according to claim 4, wherein the plasma process is performed under conditions including a pressure of from about 5 mTorr to about 20 mTorr and a flux of from about 100 sccm to about 200 sccm.

6. The method according to claim 1, wherein forming the barrier layer comprises performing a chemical vapor deposition (CVD) process using silane and ammonia.

7. The method according to claim 6, wherein the barrier layer comprises silicon nitride (SiN).

8. A semiconductor device comprising:
a substrate including a gate and lightly-doped drain (LDD) regions;
a first spacer adjacent to a first side surface of the gate;
a second spacer adjacent to a second side surface of the gate which is opposed to the first side surface;
a first barrier pattern between the gate and the first spacer and between a portion of one of the LDD regions and the first spacer;
a second barrier pattern between the gate and the second spacer and between a portion of another of the LDD regions and the second spacer; and
a source/drain region provided in each LDD region.

9. The semiconductor device according to claim 8, wherein the first barrier pattern is formed on the first side surface of the gate and a bottom surface of the first spacer, and wherein the second barrier pattern is formed on the second side surface of the gate and a bottom surface of the second spacer.

10. The semiconductor device according to claim 9, wherein the first barrier pattern is formed between an upper surface of one of the LDD regions and the bottom surface of the first spacer, and wherein the second barrier pattern is formed between an upper surface of another of the LDD regions and the bottom surface of the second spacer.

11. The semiconductor device according to claim 8, wherein the first barrier pattern comprises silicon nitride, and wherein the second barrier pattern comprises silicon nitride.

12. The semiconductor device according to claim 8, wherein the height of the first barrier pattern is approximately the same as that of the gate, and wherein the height of the second barrier pattern is approximately the same as that of the gate.

13. The semiconductor device according to claim 8, wherein the length of the first barrier pattern extending from the gate of the portion of the one of the LDD regions is approximately the same as that of the first spacer, and wherein the length of the second barrier pattern extending from the gate of the portion of the other of the LDD regions is approximately the same as that of the second spacer.
